(19) United States
(12) Patent Application Publication
(10) Pub. No.: US 2013/0292756 A1
(43) Pub. Date: Nov. 7, 2013

(54) METHOD AND APPARATUS FOR UTILIZING CONTACT-SIDEWALL CAPACITANCE IN A SINGLE POLY NON-VOLATILE MEMORY CELL

(71) Applicants: Yan Zhe Tang, Singapore (SG); Elgin Quek, Singapore (SG)

(72) Inventors: Yan Zhe Tang, Singapore (SG); Elgin Quek, Singapore (SG)

(73) Assignee: GLOBALFOUNDRIES Singapore Pte. Ltd., Singapore (SG)

(21) Appl. No.: 13/463,514

(22) Filed: May 3, 2012

(51) Int. Cl. H01L 29/788; H01L 21/336

(52) U.S. Cl. 257/316; 438/586; 257/E29.309; 257/E21.422

(57) ABSTRACT

An approach for utilizing electrical capacitance between a plurality of contacts and sidewalls to provide voltage coupling between a floating gate (FG) and a control gate (CG) is disclosed. Embodiments include providing an FG and a CG laterally separated from each other; coupling a plurality of parallel polysilicon lines to the FG; providing a plurality of contacts between the plurality of the parallel polysilicon lines and coupling the contacts to the CG; and forming an electrical capacitance between the plurality of contacts and sidewalls of the plurality of parallel polysilicon lines to provide voltage coupling between the CG and the FG.

### TECHNICAL FIELD

The present disclosure relates to design for a non-volatile memory cell. The present disclosure is particularly applicable to designs in 40 nanometer (nm) technology nodes and beyond.

### BACKGROUND

Traditional gate stack structure designs of a non-volatile memory (NVM) cell render utilization of an advanced logic design process (e.g., for embedded memory) more complex by requiring additional polysilicon deposition layers, various difficult lithography and etching steps, and considerations for thermal dissipation and performance. Further, combining the logic and the NVM processes affects electrical characteristics of the logic devices utilized in the design, which requires additional consideration in device matching (e.g., devices fabricated with baseline logic process and with embedded memory process). Still, certain NVM design methods utilize the logic process by employing I/O oxide as a tunneling oxide and further utilize different wells to couple a voltage potential to a floating gate (FG, logic polysilicon) to achieve a required voltage potential difference between the FG and a different well for program and erase operations. However, these methods yield a larger cell size since only a plate area between the polysilicon and a well/substrate are used for coupling the voltage potential to the FG. Moreover, these methods can cause reliability and performance issues due to the FG oxide covering most of the cell area (e.g., a large gate oxide area per cell), which would require high oxide quality in order to obtain a good data retention characteristic in a large memory cell array. In addition, a high coupling ratio between a control gate (CG) and the FG is required to lower the voltage for program and erase functions. In current NVMs, the CG is located under the FG. For a sufficiently low program/erase voltage, the coupling ratio must be high, which requires a large FG and CG.

A need therefore exists for a single poly memory cell design for use in advanced logic design technology, which can provide capabilities for highly efficient structure design, easier integration with logic cell designs, scalability, and increased coupling ratio between a control gate (CG) and a floating gate (FG) for coupling voltage potentials required to program and/or erase the memory cell.

### SUMMARY

An aspect of the present disclosure is a device implemented with electrical capacitance between a plurality of contacts and sidewalls to provide voltage coupling between an FG and a CG.

Another aspect of the present disclosure is a method for utilizing electrical capacitance between a plurality of contacts and sidewalls to provide voltage coupling between a FG and a CG.

Additional aspects and other features of the present disclosure will be set forth in the description which follows and in part will be apparent to those having ordinary skill in the art upon examination of the following or may be learned from the practice of the present disclosure. The advantages of the present disclosure may be realized and obtained as particularly pointed out in the appended claims.

According to the present disclosure, some technical effects may be achieved in part by a device including: a single polysilicon memory cell on a substrate including a control gate (CG) and a floating gate (FG), the CG being laterally separated from the FG; a plurality of contacts coupled to the CG and arranged in lines in a first direction on the substrate; and a plurality of parallel polysilicon lines coupled to the FG and arranged in the first direction on the substrate alternating with and in substantially close proximity with the lines of contacts, each parallel polysilicon line having sidewalls, wherein electrical capacitance between a contact and an adjacent polysilicon sidewall provides voltage coupling between the CG and the FG. Some aspects further include a dielectric medium of silicon nitride (SiN) arranged between the plurality of CG contacts and the polysilicon sidewalls.

An additional aspect of the present disclosure is a device, wherein the polysilicon thickness is 80 nm. In another aspect the device includes a first metal layer vertically coupled to the contacts. Further aspects include a device having the CG formed of the contacts and the first metal layer. In one aspect, the FG is formed of logic polysilicon and in one aspect the device further includes a word line (WL) formed of the logic polysilicon.

In other aspects a device includes a second metal layer; a bit line (BL) connected by the second metal layer; and a source line (SL) connected by the second metal layer. Further aspects include a device having the plurality of parallel polysilicon lines coupled to the FG and the FG are connected to form a fork-like pattern on the substrate. Additional aspects include a device wherein the plurality of contacts form a plurality of parallel contact lines.

Aspects of the present disclosure include: providing a FG and a CG laterally separated from each other; coupling a plurality of parallel polysilicon lines to the FG; providing a plurality of contacts between the plurality of the parallel polysilicon lines and coupling the contacts to the CG; and forming an electrical capacitance between the plurality of contacts and sidewalls of the plurality of parallel polysilicon lines to provide voltage coupling between the CG and FG. Additional aspects include providing a dielectric medium of SiN arranged between the plurality of contacts and the polysilicon sidewalls. Another aspect includes providing the polysilicon thickness at 80 nm.

Another aspect includes coupling a first metal layer vertically to the contacts. Other aspects include forming the CG, at least in part, by the contacts and the first metal layer. One aspect includes forming the FG of logic polysilicon and in one aspect providing a word line (WL) formed of the logic polysilicon. Various aspects include providing a second metal layer; providing a BL connected by the second metal layer; and providing a SL connected by the second metal layer. In another aspect the plurality of parallel polysilicon lines coupled to the FG and the FG are connected to form a fork-like pattern on the substrate. In one aspect the plurality of contacts form a plurality of parallel contact lines.

An additional aspect of the present disclosure is a device including: a single polysilicon memory cell on a substrate including a CG and a FG, the CG being laterally separated from the FG; a plurality of contacts coupled to the CG and arranged in lines in a first direction on the substrate; a plurality of parallel polysilicon lines coupled to the FG and arranged in the first direction on the substrate alternating with and in substantially close proximity with the lines of contacts, each parallel polysilicon line having sidewalls, wherein electrical capacitance between a contact and an adjacent polysilicon sidewall provides voltage coupling between the CG and the FG; a dielectric medium of SiN arranged between the plurality of contacts and the polysilicon sidewalls; and a plurality of parallel polysilicon lines coupled to the FG and the FG are connected to form a fork-like pattern on the substrate.

Additional aspects and technical effects of the present disclosure will become readily apparent to those skilled in the art from the following detailed description wherein embodiments of the present disclosure are described simply by way of illustration of the best mode contemplated to carry out the present disclosure. As will be realized, the present disclosure is capable of other and different embodiments, and its several details are capable of modifications in various obvious respects, all without departing from the present disclosure. Accordingly, the drawings and description are to be regarded as illustrative in nature, and not as restrictive.

### BRIEF DESCRIPTION OF THE DRAWINGS

The present disclosure is illustrated by way of example, and not by way of limitation, in the figures of the accompanying drawing and in which like reference numerals refer to similar elements and in which:

FIG. 1 schematically illustrates a memory cell array including a memory cell structure, in accordance with an exemplary embodiment of the present disclosure;

FIG. 2 schematically illustrates a cross section of a coupling area of the memory cell structure, in accordance with an exemplary embodiment of the present disclosure;

FIG. 3 schematically illustrates gate level structure of a 2T memory cell structure, in accordance with an exemplary embodiment of the present disclosure;

FIG. 4 schematically illustrates transistor array architecture of the memory cell structure, in accordance with an exemplary embodiment of the present disclosure;

FIG. 5 schematically illustrates dimensions of contact slot structure of the memory cell structure, in accordance with an exemplary embodiment of the present disclosure; and

FIG. 6 schematically illustrates dimensions of a standard contact array structure of the memory cell structure, in accordance with an exemplary embodiment of the present disclosure.

### DETAILED DESCRIPTION

In the following description, for the purposes of explanation, numerous specific details are set forth in order to provide a thorough understanding of exemplary embodiments. It should be apparent, however, that exemplary embodiments may be practiced without these specific details or with an equivalent arrangement. In other instances, well-known structures and devices are shown in block diagram form in order to avoid unnecessarily obscuring exemplary embodiments. In addition, unless otherwise indicated, all numbers expressing quantities, ratios, and numerical properties of ingredients, reaction conditions, and so forth used in the specification and claims are to be understood as being modified in all instances by the term “about.”

The present disclosure addresses and solves problems of low CG to FG coupling ratios, high program and erase voltages, and large cell size attendant upon formation of current gate stack structures of non-volatile memories. The problems are solved by a single poly memory cell structure in which an FG is laterally adjacent a CG and electrical capacitance between a CG contact and an adjacent FG polysilicon sidewall are employed for coupling voltage potential between the FG and the CG.

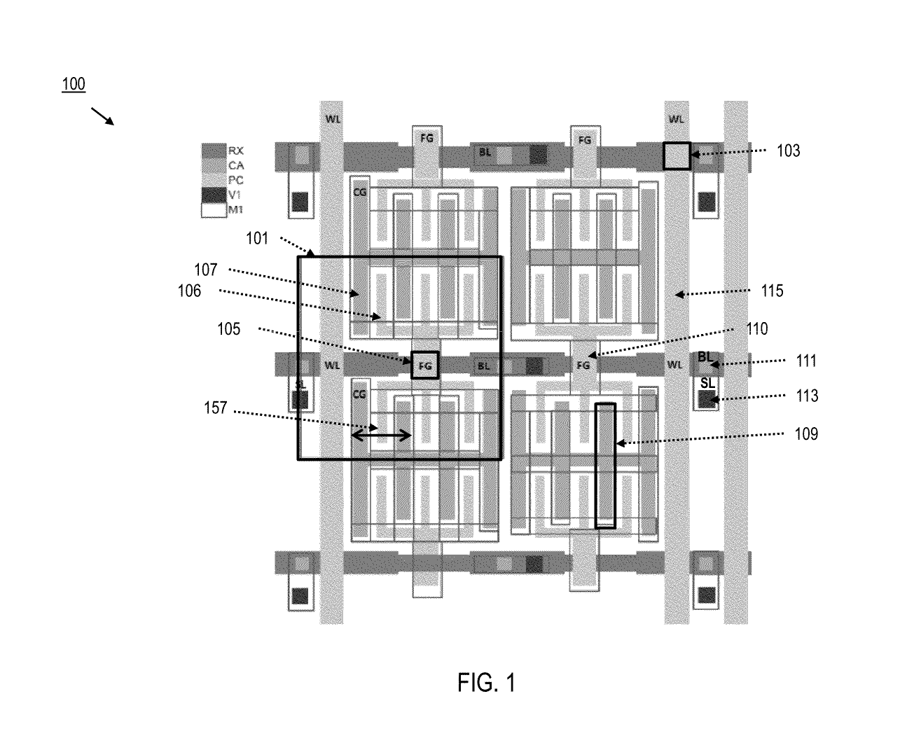

FIG. 1 schematically illustrates memory cell array 100 including a memory cell structure 101, in accordance with an exemplary embodiment of the present disclosure. The memory cell structure 101 includes active area 103 (e.g., access gate of the memory cell), FG 105 active area (e.g., gate/transistor) coupled to a plurality of parallel polysilicon lines 106 (e.g., FG lines connected in a fork-like shape), a plurality of contacts 107 (e.g., lines, segments, etc.) coupled to a CG that is formed by plurality contacts 107 and a first metal layer 109, bit line (BL) 111, source line (SL) 113, and word line (WL) 115. Further, each of the FG lines 106 is in parallel with an adjacent CG contact 107, wherein the space between an FG line 106 and a CG contact 107 includes one or more dielectrics (e.g., SiO₂ and SiN). If SiN is included, the higher dielectric constant improves coupling between the CG and the FG. The WL is connected by polysilicon, and the CG is connected by the first metal layer in the vertical direction (row); a second metal layer is used for BL 111 and SL 113 connection (column). The fork-like FG lines 106 and the CG contacts 107 are formed on a shallow trench isolation (STI) region and are designed to have a high coupling ratio for coupling a voltage potential between the CG contacts 107 and the FG lines 106.

The NVM design allows for a smaller cell area when compared to other current NVM designs without requiring additional process (e.g., mask) steps when utilizing the current standard processes. Further, a side capacitance instead of a surface capacitance is utilized for coupling a voltage potential between the FG lines 106 and the CG contacts 107. As illustrated in FIG. 1, tunneling space 110 between the FG polysilicon and the well substrate is smaller compared to the current standard design, which allows for a smaller gate oxide and increases the reliability, yield, and quality of the memory cell as it enables increased data retention.

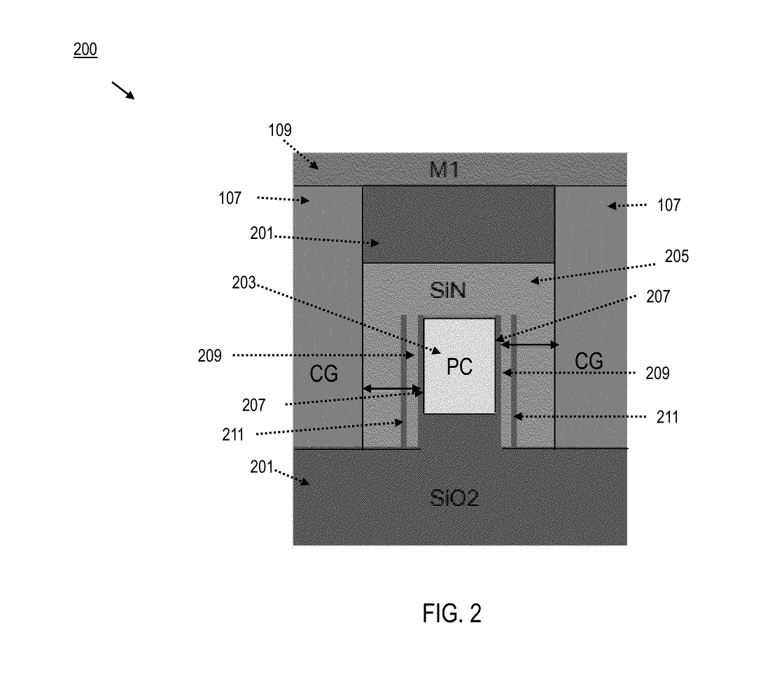

FIG. 2 schematically illustrates a cross section 200 of a coupling area of the memory cell structure 101, in accordance with an exemplary embodiment of the present disclosure. FIG. 2 shows a silicon dioxide (SiO₂) medium 201 (e.g., STI region) utilized in integrated-circuit (IC) manufacturing, logic gate (PC) 203 (e.g., FG) with sidewalls 207, CG contacts 107, SiN spacers 209, SiO₂ spacers 211, and SiN 205 between the CG contacts 107 and the PC sidewall 207, wherein capacitance between a CG contact 107 and a sidewall 207 is utilized for CG to FG coupling.

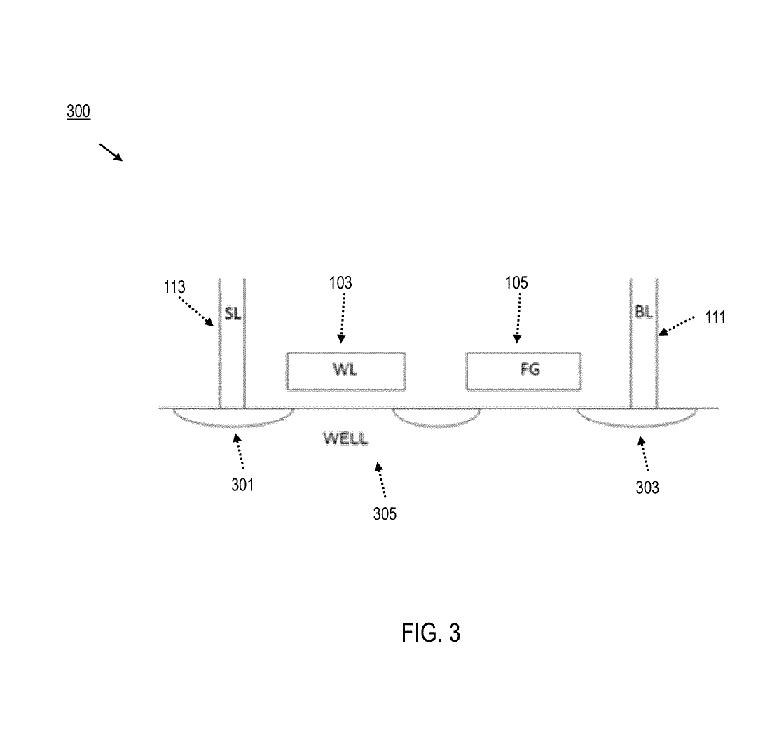

FIG. 3 schematically illustrates gate level structure 300 of a 2T memory cell structure, in accordance with an exemplary embodiment of the present disclosure. The structure 300 is a schematic cross-section along active region (RX) including source 301 and drain 303 regions. The 2T cell structure utilizes Folwer-Norheim (FN) tunneling (a field-emission process whereby electrons tunnel through a barrier in the presence of a high electric field), with the gate oxide (between FG 105 and well 305 in the substrate) being used as a tunneling oxide.

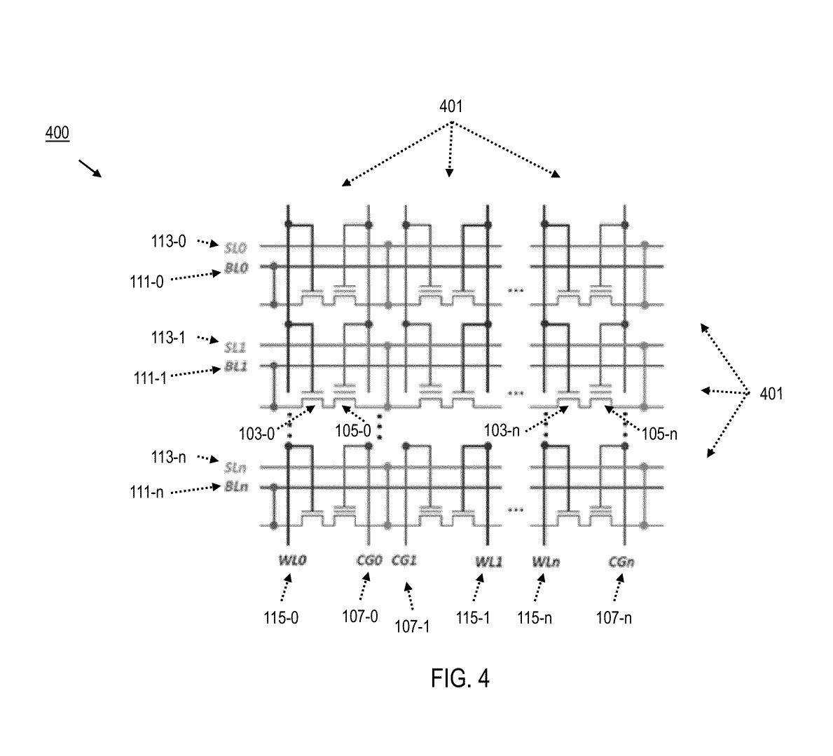

FIG. 4 schematically illustrates memory array architecture 400 of the memory cell structure 101, in accordance with an exemplary embodiment of the present disclosure. As shown in FIG. 4, memory array architecture 400 includes multiple memory cells 401 (e.g., WL transistors, FG transistors) and control architecture elements such as BL couplings 111-0 through 111-n, SL couplings 113-0 through 113-n, WL couplings 115-0 through 115-n, and CG couplings 107-0 through 107-n. One or more of the control architecture elements are utilized (e.g., activated) to access and control various transistors and elements of the memory cell structure 101 for performing one or more operations (e.g., read, write, erase).

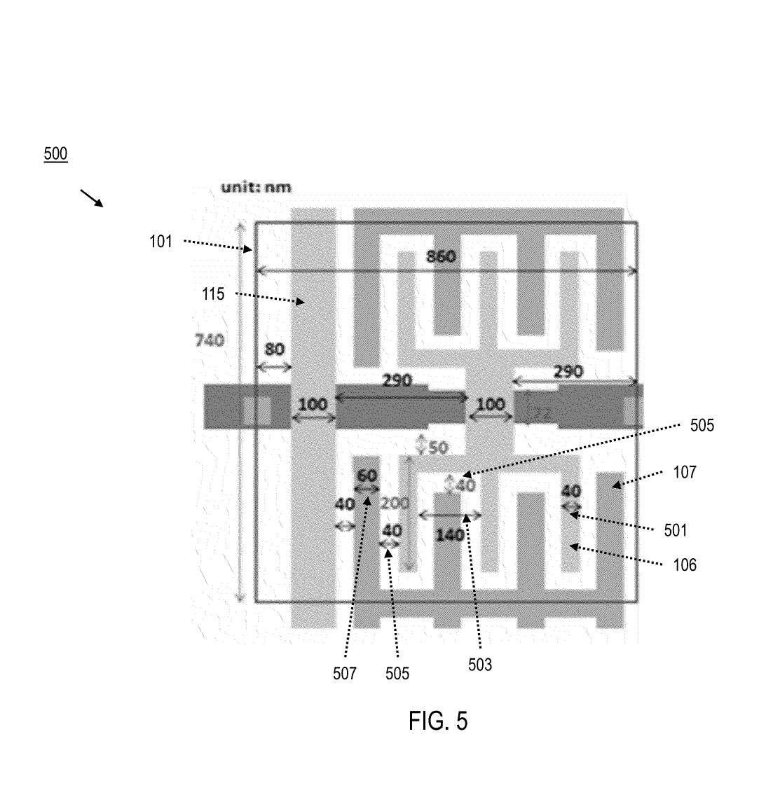

FIG. 5 schematically illustrates an example of dimensions of contact slot structure 500 of the proposed memory cell structure 101, in accordance with an exemplary embodiment of the present disclosure. FIG. 5 shows contact slot structure 500 for a compact cell size design based on a 40 nm design rule in which the cell has a width of 860 nm and a length of 740 nm. In the example, an FG line 106 having a width 501 of 40 nm is placed at a distance 503 of 140 nm away from an adjacent FG line 106 and at a distance 505 of 40 nm away from an adjacent CG line 107. Further, a CG contact 107 has a width (e.g., 60 nm) and is placed at a distance 505 of 40 nm away from a parallel and/or a perpendicular FG line 106. The dimensions shown are merely exemplary, and are easily scalable due to the lateral positioning of the CG contacts 107 and the FG lines 106.

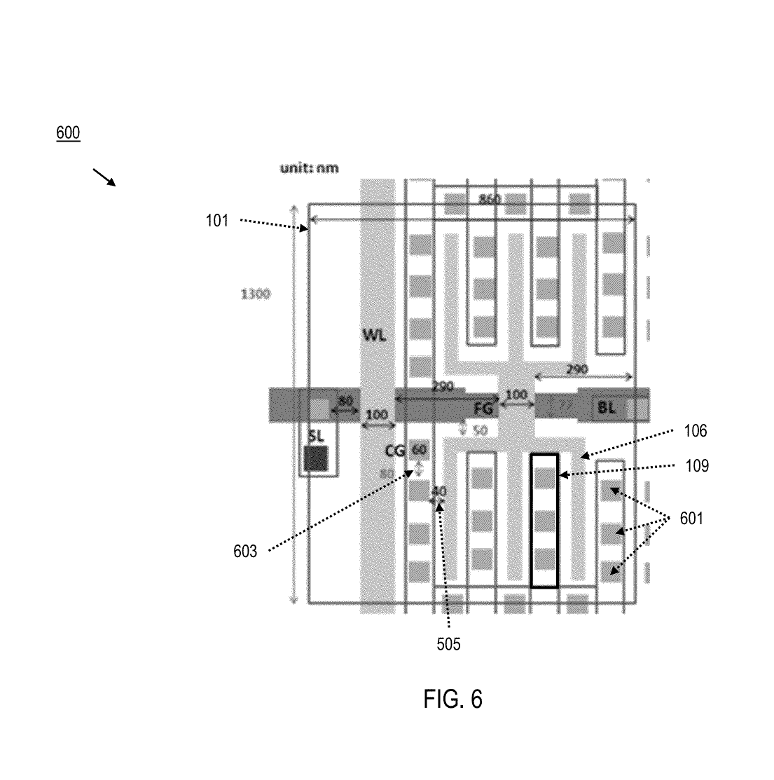

FIG. 6 schematically illustrates an example of dimensions of a standard contact array structure 600 used with the memory cell structure 101, in accordance with an exemplary embodiment of the present disclosure. FIG. 6 shows the standard contact array structure 600, with a cell width of 860 nm and cell length of 1300 nm (which is greater than for the contact slot structure shown in FIG. 5), having FG lines 106 and standard contact array formation having columns of multiple contacts 601 (each a 60×60 nm square) in parallel with the FG lines 106, still at the distance 505 (e.g., 40 nm) away from an adjacent FG line 106, and at a distance 603 (e.g., 60 nm) away from an adjacent contact 601.

Table 1 below shows example characteristics of the contact slot structure shown in FIG. 5, the standard contact array shown in FIG. 6, and the current reference design solutions. For the exemplary coupling ratio calculations, tunneling oxide thickness is 8 nm, polysilicon (sidewall) to contact spacing is 40 nm, and polysilicon thickness is 80 nm. As indicated, a memory cell area size of 0.6364 um² for the contact slot and 1.118 um² for the standard contact array, can provide higher FG to CG coupling ratios of 89% (for the contact slot) and 88% (for the standard contact array), wherein the coupling ratio in the current standard technology is very low since the size of the control gate and the floating gate is limited and the dielectric constant of the dielectric is low. The utilization of a big sidewall area and the SiN dielectric, which has a higher (e.g., twice) dielectric constant as compared to SiO₂ between CG and FG provides the increased coupling ratio. Further, lower FG to substrate coupling ratios of 9.6% (for the contact slot) and 7.7% (for the standard contact array) can be achieved due to the smaller FG size. Furthermore, as indicated in the table 1, the cell size of the NVM is 4% (for the contact slot) and 7% (for the standard contact array) of the reference cell, wherein a reduced cell size in the 40 nm technology node provides for the well/substrate to have higher coupling ratios for coupling voltage between the FG and CG. Moreover, the FG oxide area per cell is 0.6% of the reference cell, which provides for a more reliable memory cell. Additionally, as indicated, the dimensions are merely exemplary, and the NVM cell design embodiments of the present disclosure can provide further advantages in reducing the cell size which require more strict design rules such as polysilicon to contact spacing, polysilicon width, and contact width, wherein the current reference cell may only be capable of providing limited opportunity for reducing cell size since it utilizes standard I/O transistors, which require larger gate area for FG to CG coupling.

TABLE 1

| | | This invention | |
|---|---|---|---|
| | This invention | Standard CA | |
| Unit: um | CA Slot option | option | Reference |
| Y pitch | 0.86 | 0.86 | ~4.5 |
| X pitch | 0.74 | 1.3 | ~3.6 |
| Area | 0.6364 | 1.118 | ~16.2 |
| FG oxide area/cell | 0.0072 | 0.0072 | 1.2445 |
| Coupling Ratio | | | |
| FG->CG | 88.9% | 87.7% | 82% |
| FG->Sub | 9.6% | 7.7% | 9% |

The embodiments of the present disclosure can achieve several technical effects, including use of current standard logic processes (e.g., no need for additional mask and/or process steps), a higher CG to FG coupling ratio with lower program and erase voltage requirements (e.g., can be generated by I/O transistors), smaller cell size compared to the existing art, and scalability for use in smaller technology nodes (e.g., shrinkable). Embodiments of the present disclosure enjoy utility in various industrial applications as, for example, microprocessors, smart phones, mobile phones, cellular handsets, set-top boxes, DVD recorders and players, automotive navigation, printers and peripherals, networking and telecom equipment, gaming systems, and digital cameras. The present disclosure therefore enjoys industrial applicability in any of various types of highly integrated semiconductor devices.

In the preceding description, the present disclosure is described with reference to specifically exemplary embodiments thereof. It will, however, be evident that various modifications and changes may be made thereto without departing from the broader spirit and scope of the present disclosure, as set forth in the claims. The specification and drawings are, accordingly, to be regarded as illustrative and not as restrictive. It is understood that the present disclosure is capable of using various other combinations and embodiments and is capable of any changes or modifications within the scope of the inventive concept as expressed herein.

what is claimed is:

1. A device comprising:
a single polysilicon memory cell on a substrate including a control gate (CG) and a floating gate (FG), the CG being laterally separated from the FG;
a plurality of contacts coupled to the CG and arranged in lines in a first direction on the substrate; and
a plurality of parallel polysilicon lines coupled to the FG and arranged in the first direction on the substrate alternating with and in substantially close proximity with the lines of contacts, each parallel polysilicon line having sidewalls,
wherein electrical capacitance between a contact and an adjacent polysilicon sidewall provides voltage coupling between the CG and the FG.

2. The device according to claim 1, further comprising:
a dielectric medium of silicon nitride (SiN) arranged between the plurality of CG contacts and the polysilicon sidewalls.

3. The device according to claim 2, wherein the polysilicon thickness is 80 nanometers (nm).

4. The device according to claim 1, further comprising a first metal layer vertically coupled to the contacts.

5. The device according to claim 4, wherein the CG is formed of the contacts and the first metal layer.

6. The device according to claim 5, wherein the FG is formed of logic polysilicon.

7. The device according to claim 5, further comprising a word line (WL) formed of the logic polysilicon.

8. The device according to claim 7, further comprising:
a second metal layer;
a bit line (BL) connected by the second metal layer; and
a source line (SL) connected by the second metal layer.

9. The device according to claim 1, wherein the plurality of parallel polysilicon lines coupled to the FG and the FG are connected to form a fork-like pattern on the substrate.

10. The device according to claim 1, wherein the plurality of contacts form a plurality of parallel contact lines.

11. A method comprising:
providing a floating gate (FG) and a control gate (CG) laterally separated from each other;
coupling a plurality of parallel polysilicon lines to the FG;
providing a plurality of contacts between the plurality of the parallel polysilicon lines and coupling the contacts to the CG; and
forming an electrical capacitance between the plurality of contacts and sidewalls of the plurality of parallel polysilicon lines to provide voltage coupling between the CG and FG.

12. The method of claim 11, further comprising:
providing a dielectric medium of silicon nitride (SiN) arranged between the plurality of CG contacts and the polysilicon sidewalls,
wherein the polysilicon thickness is 80 nanometers (nm).

13. The method of claim 11, further comprising:
coupling a first metal layer vertically to the contacts.

14. The method of claim 13, further comprising:
forming the CG, at least in part, by the contacts and the first metal layer.

15. The method of claim 14, further comprising:
forming the FG of logic polysilicon.

16. The method of claim 15, further comprising:providing a word line (WL) formed of the logic polysilicon.

17. The method of claim 15, further comprising:
providing a second metal layer;
providing a bit line (BL) connected by the second metal layer; and
providing a source line (SL) connected by the second metal layer.

18. The method of claim 11, wherein the plurality of parallel polysilicon lines coupled to the FG and the FG are connected to form a fork-like pattern on the substrate.

19. The method of claim 11, wherein the plurality of contacts form a plurality of parallel contact lines.

20. A device comprising:
a single polysilicon memory cell on a substrate including a control gate (CG) and a floating gate (FG), the CG being laterally separated from the FG;
a plurality of contacts coupled to the CG and arranged in lines in a first direction on the substrate;
a plurality of parallel polysilicon lines coupled to the FG and arranged in the first direction on the substrate alternating with and in substantially close proximity with the lines of contacts, each parallel polysilicon line having sidewalls,
wherein electrical capacitance between a contact and an adjacent polysilicon sidewall provides voltage coupling between the CG and the FG;
a dielectric medium of silicon nitride (SiN) arranged between the plurality of CG contacts and the polysilicon sidewalls; and
a plurality of parallel polysilicon lines coupled to the FG and the FG are connected to form a fork-like pattern on the substrate.
